(19) United States
(12) Patent Application Publication
(10) Pub. No.: US 2013/0010415 A1
(43) Pub. Date: Jan. 10, 2013

(54) DISPLAY DEVICE

(75) Inventor: Kazuya Hatta, Osaka-shi (JP)

(73) Assignee: SHARP KABUSHIKI KAISHA, Osaka-shi, Osaka (JP)

(21) Appl. No.: 13/636,226

(22) PCT Filed: Mar. 29, 2011
(86) PCT No.: PCT/JP2011/057726

§ 371 Date: Sep. 20, 2012

(30) Foreign Application Priority Data
Apr. 1, 2010 (JP) 2010-085066

(51) Int. Cl. H05K 7/02

(52) U.S. Cl. 361/679.01

(57) ABSTRACT

Disclosed is a display device facilitating reduced assembly time and disassembly time. In a liquid-crystal display device, protrusion parts and hook parts are disposed upon a frame. On a front side bezel are disposed notch parts wherein the protrusion parts are hooked, and hook holes wherein the hook parts are hooked by the protrusion parts being slid along the notch parts. On a rear side bezel are disposed notch parts wherein the protrusion parts are hooked, and hook holes wherein the hook parts are hooked by the protrusion parts being slid along the notch parts. The hook holes have a function of restricting movement of the hook parts in the B1 direction.

### TECHNICAL FIELD

The present invention relates to a display device, more particularly, to a display device that includes a frame and a bezel.

### BACKGROUND ART

Conventionally, a display device which includes a frame and a bezel is known (e.g., see a patent document 1). The above patent document 1 discloses a display device that includes: a liquid crystal display (display panel); a cover (frame) that houses the liquid crystal display; a wide (or narrow) cover (front side bezel) that is disposed on a front side of the cover (frame); and a rear cover (rear side bezel) that is disposed on a rear side of the cover (frame).

In this display device, the wide (or narrow) cover (front side bezel), the liquid crystal display, the cover (frame), and the rear cover (rear side bezel) are stacked on one another, screwed, and fixed.

Because of this, in the above patent document 1, during an assembly time of the display device, the screwing is necessary, accordingly, there is a disadvantage that it takes a long time to assemble the display device.

Accordingly, a display device capable of improving the above disadvantage is proposed.

FIG. 31 is an exploded perspective view showing a structure of a display device as a conventional example that is capable of improving the above disadvantage. A display device 1001 as the conventional example, as shown in FIG. 31, includes: a liquid crystal display panel 1002; a frame 1010 that houses the liquid crystal display device 1002; a front side bezel 1020 and a rear side bezel 1030 that are mounted on the frame 1010.

The liquid crystal display panel 1002 is composed of a pair of glass boards that sandwich a not-shown liquid crystal layer.

The frame 1010 is formed to be a frame shape that includes four side wall portions (outer edge portions) 1011. In an inside of these four side wall portions 1011, an optical sheet and a light source and the like which are not shown are also housed.

Besides, the four side wall portions 1011 are provided with: a plurality of protrusion portions 1011a that engage with later-described engagement holes 1022a of the front side bezel 1020; and a plurality of protrusion portions 1011b that engage with later-described engagement holes 1032a of the rear side bezel 1030.

The front side bezel 1020 is formed to be a frame shape, and formed slightly larger than the frame 1010 and the rear side bezel 1030 when viewed from top.

Besides, the front side bezel 1020 includes a front surface portion 1021 and four side wall portions 1022. The front surface portion 1021 is provided with an opening portion 1021a. Besides, the four side wall portions 1022 are provided with a plurality of engagement holes 1022a at positions that correspond to the protrusion portions 1011a of the frame 1010.

The rear side bezel 1030 is formed slightly larger than the frame 1030 when viewed from top.

The rear side bezel 1030 includes a rear surface portion 1031 and four side wall portions 1032. The four side wall portions 1032 are provided with a plurality of engagement holes 1032a at positions that correspond to the protrusion portions 1011b of the frame 1010.

Besides, the four side wall portions 1032 are provided with a plurality of cutout portions 1032b such that the side wall portions 1032 do not touch the protrusion portions 1011a of the frame 1010.

In the conventional display device 1001 shown in FIG. 31, in a case of assembling the display device 1001, the rear side bezel 1030 is fitted to the frame 1010 from the rear side. According to this, the engagement holes 1032a of the four side wall portions 1032 of the rear side bezel 1030 engage with the protrusion portions 1011b of the four side wall portions 1011 of the frame 1010, whereby the rear side bezel 1030 is fixed to the frame 1010.

And, the front side bezel 1020 is fitted to the frame 1010 from the front side. According to this, the engagement holes 1022a of the four side wall portions 1022 of the front side bezel 1020 engage with the protrusion portions 1011a of the four side wall portions 1011 of the frame 1010, whereby the front side bezel 1020 is fixed to the frame 1010.

As described above, in the display device 1001 as the conventional example shown in FIG. 31, it is possible to assemble the display device 1001 without using a screw, accordingly, it is possible to improve the assembly workability and shorten the assembly time of the display device 1001.

Here, the structure, in which the protrusion portions formed on the four side wall portions (outer edge portions) of the frame engage with the engagement holes formed in the four side wall portions of the bezel, is disclosed in patent documents 2 and 3, for example.

### CITATION LIST

### Patent Literature

PLT1: JP-A-2001-92561
PLT2: JP-A-1996-5998
PLT3: JP-A-2002-303851

### SUMMARY OF INVENTION

### Technical Problem

However, in the display device 1001 as the conventional example shown in FIG. 31, the engagement holes 1022a and the protrusion portions 1011a are disposed in and on the four edges (four side wall portions), accordingly, there are problems that the workability when demounting the front side bezel 1020 from the frame 1010 deteriorates and it takes a long time to demount the front side bezel 1020 from the frame 1010.

Likewise, in this display device 1001, the engagement holes 1032a and the protrusion portions 1011b are disposed in and on the four edges (four side wall portions), accordingly, there are problems that the workability when demounting the rear side bezel 1030 from the frame 1010 deteriorates and it takes a long time to demount the rear side bezel 1030 from the frame 1010.

In other words, in the display device as the conventional example, there is a problem that it takes a long time to disassemble the display device 1001.

The present invention has been made to solve the above problems, and it is an object of the present invention to provide a display device that is capable of shorten an assembly time and a disassembly time.

### Solution to Problem

To achieve the above object, a display device according to one aspect of the present invention includes: a frame that holds a display panel; and a bezel that is disposed on at least one of a front side and a rear side of the frame; wherein one of the frame and the bezel is provided with a protrusion portion; the other of the frame and the bezel is provided with a guide portion that includes a first guide portion which is engaged with the protrusion portion and extends in a first direction along a surface direction of the display panel; one of the frame and the bezel is provided with a hook portion; the other of the frame and the bezel is provided with an engagement hole that is engaged with the hook portion when the protrusion portion is slid in the first direction along the first guide portion of the guide portion; and the engagement hole has a function to alleviate the hook portion moving in a direction along the first direction.

Here, the present specification describes that one of the frame and the bezel is provided with the protrusion portion and one of the frame and the bezel is provided with the hook portion, which however means that both of the protrusion portion and the hook portion may be disposed on the same member (the frame or the bezel), or the protrusion portion and the hook portion may be disposed on separate members (the frame and the bezel). It goes without saying that this applies to the guide portion and the engagement hole. Besides, this applies to a positioning portion and a positioning hole that are described later; for example, the positioning portion may be disposed on the same member as the protrusion portion or may be disposed on a member separate from the protrusion portion.

In the display device according to this one aspect, as described above, the one of the frame and the bezel is provided with the protrusion portion; the other of the frame and the bezel is provided with the guide portion that is engaged with the protrusion portion; the one of the frame and the bezel is provided with the hook portion; and the other of the frame and the bezel is provided with the engagement hole that is engaged with the hook portion when the protrusion portion is slid in the first direction along the first guide portion of the guide portion. According to this, by sliding the protrusion portion in the first direction along the guide portion, it is possible to engage the hook portion with the engagement hole and fix the bezel to the frame. In other words, it is possible to assemble the display device without using a screw, accordingly, it is possible to improve the assembly workability and shorten the assembly time of the display device. Besides, it is possible to improve the workability when disassembling the display device, accordingly, it is also possible to shorten the disassembly time of the display device.

Besides, in the display device according to the one aspect, as described above, by forming the first guide portion of the guide portion to extend in the first direction along the surface direction of the display panel, by means of the protrusion portion and the first guide portion of the guide portion, it is possible to alleviate the bezel moving with respect to the frame in a direction that intersects the surface direction of the display panel. Besides, the engagement hole is formed to be engaged with the hook portion when the protrusion portion is slid in the first direction along the first guide portion of the guide portion and to alleviate the hook portion moving in the direction along the first direction. According to this, by means of the hook portion and the engagement hole, it is possible to alleviate the bezel moving in the surface direction of the display panel with respect to the frame. In other words, it is possible to alleviate the bezel coming off the frame.

Besides, according to the above structure, it is not necessary to dispose the hook portion and the engagement hole on and in the four edges (four outer edge portions) of the frame and the bezel, accordingly, it is possible to more improve the assembly workability and disassemble workability of the display device. According to this, it is possible to more shorten the assembly time and disassembly time of the display device. Here, for example, in a case where the hook portion and the engagement hole are disposed on and in the four edges (four outer edge portions) of the frame and the bezel, thanks to dimensional unevenness of the components, a difference occurs in fitting workability (or demounting workability). Specifically, a disadvantage occurs, in which it is easy to fit in (or demount from) two edges (two outer edge portions) but hard to fit (or hard to demount) in the remaining two edges and the like.

In the display device according to the above one aspect, preferably, the frame includes a plurality of the outer edge portions, and the hook portion or the engagement hole is disposed on or in one outer edge portion of the plurality of outer edge portions. According to this structure, compared with a case where the hook portion or the engagement hole is disposed on or in two or more outer edge portions of the plurality of outer edge portions, it is possible to decrease the fixing (engagement) portions, accordingly, it is possible to more improve the workability when demounting the bezel from the frame. According to this, it is possible to more shorten the disassembly time of the display device.

In the display device according to the above one aspect, preferably, in a case where the hook portion is disposed on the frame, the hook portion is disposed near an end portion of the frame in the slide direction of the bezel when mounting the bezel on the frame; in a case where the hook portion is disposed on the bezel, the hook portion is disposed near an end portion of the bezel in a direction opposite to the slide direction. According to this structure, during a time the bezel is slid with respect to the frame, it is possible to alleviate the hook portion touching the member (bezel or frame) in which the engagement hole is disposed, accordingly, it is possible to alleviate the bezel becoming hard to slide with respect to the frame. According to this, it is possible to alleviate the assembly workability and disassembly workability of the display device deteriorating.

In the display device according to the above one aspect, preferably, the guide portion includes a second guide portion that is connected to the first guide portion and extends in a direction which intersects the surface direction of the display panel. According to this structure, by moving the protrusion portion along the second guide portion, thereafter, sliding the protrusion portion along the first guide portion, it is possible to easily fix the bezel to the frame. Besides, by disposing the second guide portion on the guide portion, compared with a case where the guide portion is formed on the first guide portion only that extends in the first direction along the surface direction of the display panel, it is possible to shorten a moving distance of the bezel with respect to the frame. According to this, it is possible to improve the assembly workability and disassembly workability of the display device.

In the display device according to the above one aspect, preferably, an end portion of one of the frame and the bezel in the direction opposite to the slide direction of the bezel when mounting the bezel on the frame is provided with a positioning portion that protrudes in a direction along the slide direction; and an end portion of the other of the frame and the bezel in the direction opposite to the slide direction is provided with a positioning hole that engages with the positioning portion. According to this structure, in the direction opposite to the slide direction of the bezel when mounting the bezel on the frame, it is possible to fix the bezel to the frame with high accuracy, and by means of the positioning portion and the positioning hole, it is possible to alleviate the bezel moving (coming off) with respect to the frame in the direction that intersects the surface direction of the display panel.

In the display device that is provided with the above positioning portion and positioning hole, preferably, the frame is formed of a resin; and the positioning portion is formed integrally with the frame. According to this structure, it is possible to easily dispose the positioning portion on the frame.

In the display device according to the above one aspect, preferably, the frame is formed of a resin; and the protrusion portion is formed integrally with the frame. According to this structure, it is possible to easily dispose the protrusion portion on the frame. Here, in a case where the guide portion is disposed on the resin frame, a slide core becomes necessary for a forming mold of the frame, a structure of the forming mold becomes complicated, and the cost becomes high.

In the display device according to the above one aspect, preferably, the frame is formed of a resin; and the hook portion is formed integrally with the frame. According to this structure, it is possible to easily dispose the hook portion on the frame.

In the display device according to the above one aspect, preferably, the bezel includes a front side bezel disposed on the front side of the frame and a rear side bezel disposed on the rear side of the frame. As described above, in the case where the bezel includes the front side bezel and the rear side bezel, the time shortening effect becomes double, which is more effective.

In the display device in which the bezel includes the front side bezel and the rear side bezel, preferably, the protrusion portion is disposed on the frame; the guide portion is disposed on the front side bezel and the rear side bezel; and the protrusion portion of the frame is engaged with both of the guide portion of the front side bezel and the guide portion of the rear side bezel. According to this structure, it is not necessary to dispose separately the protrusion portion for fixing the front side bezel and the protrusion portion for fixing the rear side bezel. Here, in a case where the protrusion portion for the front side bezel for engaging with the guide portion of the front side bezel and the protrusion portion for the rear side bezel for engaging with the guide portion of the rear side bezel are separately disposed on the frame, for example, it is necessary to dispose a cutout portion on the rear side bezel for avoiding the protrusion portion for the front side bezel.

In the display device in which the bezel includes the front side bezel and the rear side bezel, preferably, an end portion of the frame in the direction opposite to the slide direction of the bezel when mounting the bezel on the frame is provided with a positioning portion that protrudes in the direction along the slide direction; an end portion of the front side bezel and an end portion of the rear side bezel in the direction opposite to the slide direction are provided with a positioning hole that engages with the positioning portion; and the positioning portion of the frame is engaged with both of the positioning hole of the front side bezel and the positioning hole of the rear side bezel. According to this structure, in the direction opposite to the slide direction of the bezel when mounting the bezel on the frame, it is possible to fix the bezel to the frame with high accuracy, and by means of the positioning portion and the positioning hole, it is possible to alleviate the bezel moving with respect to the frame in the direction that intersects the surface direction of the display panel.

Besides, by engaging the positioning portion of the frame with both of the positioning hole of the front side bezel and the positioning hole of the rear side bezel, it is not necessary to dispose separately the positioning portion for fixing the front side bezel and the positioning portion for fixing the rear side bezel. Here, in a case where the positioning portion for the front side bezel for engaging with the positioning hole of the front side bezel and the positioning portion for the rear side bezel for engaging with the positioning hole of the rear side bezel are separately disposed on the frame, for example, it is necessary to dispose a cutout portion on the rear side bezel for avoiding the positioning portion for the front side bezel.

In the display device according to the above one aspect, preferably, the frame includes a plurality of outer edge portions; and the protrusion portion or the guide portion is disposed on a pair of outer edge portions of the plurality of outer edge portions that are disposed to oppose each other. According to this structure, it is possible to more alleviate the bezel coming off the frame.

In the display device according to the above one aspect, preferably, the guide portion includes a cutout portion. According to this structure, it is possible to easily disposes the guide portion on the other of the frame and the bezel.

In the display device in which the guide portion includes the cutout portion, preferably, the protrusion portion is disposed on the frame and protrudes outward from the bezel. According to this structure, it is possible to more alleviate the protrusion portion coming off the guide portion (cutout portion), accordingly, it is possible to more alleviate the bezel coming off the frame.

In the display device according to the above one aspect, preferably, the protrusion portion is formed to be an L shape. According to this structure, it is possible to more alleviate the protrusion portion coming off the guide portion, accordingly, it is possible to more alleviate the bezel coming off the frame.

### Advantageous Effects of Invention

As described above, according to the present invention, it is possible to easily obtain a display device that is capable of shortening an assembly time and a disassembly time.

### BRIEF DESCRIPTION OF DRAWINGS

FIG. 1 is an exploded perspective view showing a structure of a liquid crystal display device according to an embodiment of the present invention.

FIG. 2 is a plan view showing a frame structure of the liquid crystal display device according to the embodiment of the present invention shown in FIG. 1.

FIG. 3 is an enlarged sectional view showing the frame structure of the liquid crystal display device according to the embodiment of the present invention shown in FIG. 1.

FIG. 4 is a bottom view showing the frame structure of the liquid crystal display device according to the embodiment of the present invention shown in FIG. 1.

FIG. 5 is an enlarged sectional view showing the frame structure of the liquid crystal display device according to the embodiment of the present invention shown in FIG. 1.

FIG. 6 is a plan view showing a structure of a front side bezel of the liquid crystal display device according to the embodiment of the present invention shown in FIG. 1.

FIG. 7 is a side view showing the structure of the front side bezel of the liquid crystal display device according to the embodiment of the present invention shown in FIG. 1.

FIG. 8 is a bottom view showing a structure of a rear side bezel of the liquid crystal display device according to the embodiment of the present invention shown in FIG. 1.

FIG. 9 is a side view for describing an assembly method and a disassembly method of the liquid crystal display device according to the embodiment of the present invention shown in FIG. 1.

FIG. 10 is a side view for describing the assembly method and the disassembly method of the liquid crystal display device according to the embodiment of the present invention shown in FIG. 1.

FIG. 11 is a bottom view for describing the assembly method and the disassembly method of the liquid crystal display device according to the embodiment of the present invention shown in FIG. 1.

FIG. 12 is a side view for describing the assembly method and the disassembly method of the liquid crystal display device according to the embodiment of the present invention shown in FIG. 1.

FIG. 13 is a side view for describing the assembly method and the disassembly method of the liquid crystal display device according to the embodiment of the present invention shown in FIG. 1.

FIG. 14 is a side view for describing the assembly method and the disassembly method of the liquid crystal display device according to the embodiment of the present invention shown in FIG. 1.

FIG. 15 is a bottom view for describing the assembly method and the disassembly method of the liquid crystal display device according to the embodiment of the present invention shown in FIG. 1.

FIG. 16 is an enlarged side view for describing the assembly method and the disassembly method of the liquid crystal display device according to the embodiment of the present invention shown in FIG. 1.

FIG. 17 is an enlarged bottom view for describing the assembly method and the disassembly method of the liquid crystal display device according to the embodiment of the present invention shown in FIG. 1.

FIG. 18 is an enlarged sectional view for describing the assembly method and the disassembly method of the liquid crystal display device according to the embodiment of the present invention shown in FIG. 1.

FIG. 19 is a side view for describing the assembly method and the disassembly method of the liquid crystal display device according to the embodiment of the present invention shown in FIG. 1.

FIG. 20 is a side view for describing the assembly method and the disassembly method of the liquid crystal display device according to the embodiment of the present invention shown in FIG. 1.

FIG. 21 is a plan view for describing the assembly method and the disassembly method of the liquid crystal display device according to the embodiment of the present invention shown in FIG. 1.

FIG. 22 is a side view for describing the assembly method and the disassembly method of the liquid crystal display device according to the embodiment of the present invention shown in FIG. 1.

FIG. 23 is a side view for describing the assembly method and the disassembly method of the liquid crystal display device according to the embodiment of the present invention shown in FIG. 1.

FIG. 24 is a side view for describing the assembly method and the disassembly method of the liquid crystal display device according to the embodiment of the present invention shown in FIG. 1.

FIG. 25 is a plan view for describing the assembly method and the disassembly method of the liquid crystal display device according to the embodiment of the present invention shown in FIG. 1.

FIG. 26 is an enlarged side view for describing the assembly method and the disassembly method of the liquid crystal display device according to the embodiment of the present invention shown in FIG. 1.

FIG. 27 is an enlarged plan view for describing the assembly method and the disassembly method of the liquid crystal display device according to the embodiment of the present invention shown in FIG. 1.

FIG. 28 is an enlarged sectional view for describing the assembly method and the disassembly method of the liquid crystal display device according to the embodiment of the present invention shown in FIG. 1.

FIG. 29 is a perspective view showing a bezel structure of a liquid crystal display device according to a first modification of the present invention.

FIG. 30 is a side view showing a bezel structure and a frame structure of a liquid crystal display device according to a second modification of the present invention.

FIG. 31 is an exploded perspective view showing a structure of a display device according to a conventional example.

### DESCRIPTION OF EMBODIMENTS

Hereinafter, embodiments of the present invention are described with reference to the drawings.

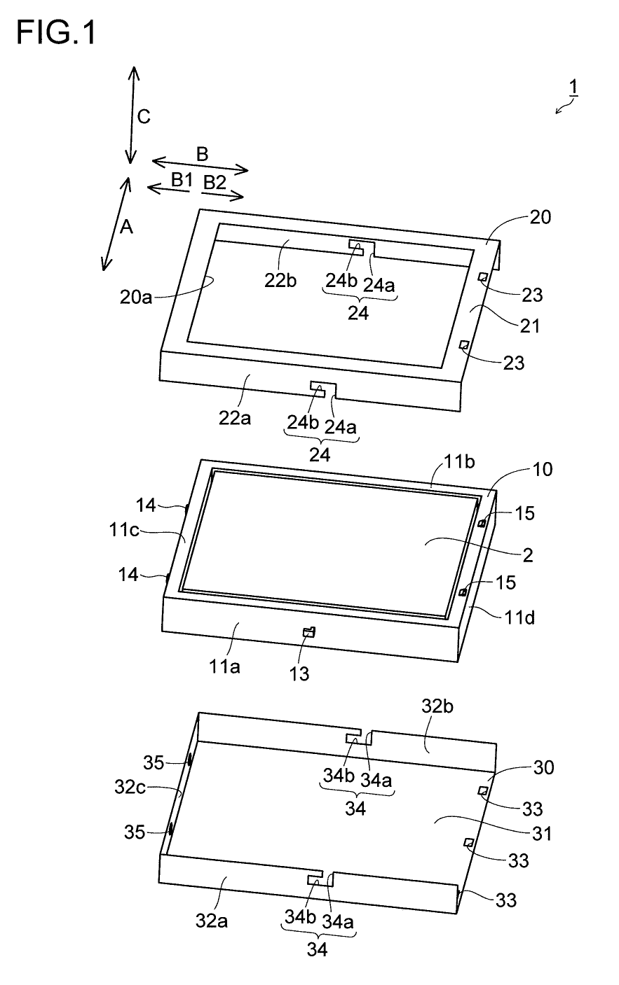

First, with reference to FIG. 1 to FIG. 8, a structure of a liquid crystal display device 1 according to an embodiment of the present invention is described.

The liquid crystal display device 1 according to the embodiment of the present invention is used for mobile devices such as a mobile phone and the like, for example. Besides, the liquid crystal display device 1, as shown in FIG. 1, includes: a liquid crystal display panel 2; a frame 10 that houses and holds the liquid crystal display panel 2; a front side bezel 20 that is disposed on a front side (upper side) of the frame 10; and a rear side bezel 30 that is disposed on a rear side (lower side) of the frame 10. Here, the liquid crystal display device 1 is an example of the “display device” of the present invention, and the liquid crystal display panel 2 is an example of a “display panel” of the present invention. Besides, the front side bezel 20 and the rear side bezel 30 are an example of a “bezel” of the present invention.

The liquid crystal display panel 2 is composed of a pair of glass boards that sandwich a not-shown liquid crystal layer.

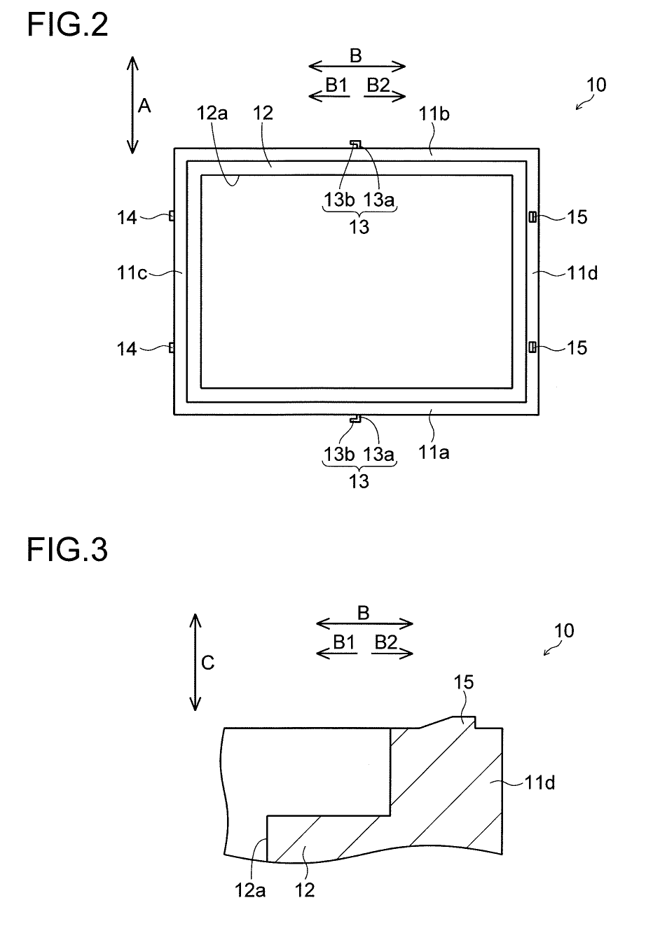

The frame 10 is formed of a resin, and when viewed from top, is made to be substantially a rectangular frame shape. Besides, the frame 10 includes: a pair of side wall portions 11a and 11b that are disposed to oppose each other; a pair of side wall portions 11c and 11d that are disposed to oppose each other; and a base portion 12 (see FIG. 2) that protrudes inward from the four side wall portions 11a to 11d. In an inside of these four side wall portions 11a to 11d, the liquid crystal display panel 2 is housed. Besides, in the inside of the four side wall portions 11a to 11d, an optical sheet, a light source, a reflection sheet and the like which are not shown are also housed. Here, the side wall portions 11a to 11d are an example of an “outer edge portion” of the present invention, and the pair of side wall portions 11a and 11b are an example of a “pair of outer edge portions” of the present invention.

The pair of side wall portions 11a and 11b are integrally provided with protrusion portions 13 that engage with later-described cutout portions 24 and 34 of the front side bezel 20 and the rear side bezel 30. This protrusion portion 13, as shown in FIG. 2, is formed to be an L shape when viewed from top, and includes a portion 13a that protrudes outward in a short-edge direction (A direction) of the frame 10, and a portion 13b that extends in a long-edge direction (B direction (a direction that meets the A direction at right angles)) of the frame 10. Here, the B direction is an example of a “direction along a slide direction” of the present invention.

Besides, the protrusion 13 is formed to protrude in the A direction outward from the front side bezel 20 and the rear side bezel 30.

The side wall portion 11c (end portion in one direction (B1 direction) in the long-edge direction of the frame 10) is integrally provided with a plurality of (two) positioning portions 14 that protrude outward (B direction) and engage with later-described positioning holes 25 (see FIG. 7) of the front side bezel 20 and later-described positioning holes 35 (see FIG. 1) of the rear side bezel 30. The positioning portion 14 is formed to be a cylindrical shape or a conical trapezoidal shape. Here, the B1 direction is an example of a “first direction” of the present invention.

A front surface (upper surface) of the side wall portion 11d is integrally provided with a plurality of (two) hook portions 15 that protrude frontward (upward) and engage with later-described engagement holes 23 (see FIG. 1) of the front side bezel 20. In other words, the hook portion 15 is formed near an end portion in the other direction (B2 direction) in the long-edge direction of the frame 10. Besides, the hook portion 15, as shown in FIG. 3, is formed to have a trapezoidal sectional shape, and an end surface of the hook portion 15 in the B2 direction is formed to be perpendicular to the front surface (upper surface) of the side wall portion 11d. Here, the B2 direction is an example of the “slide direction” of the present invention.

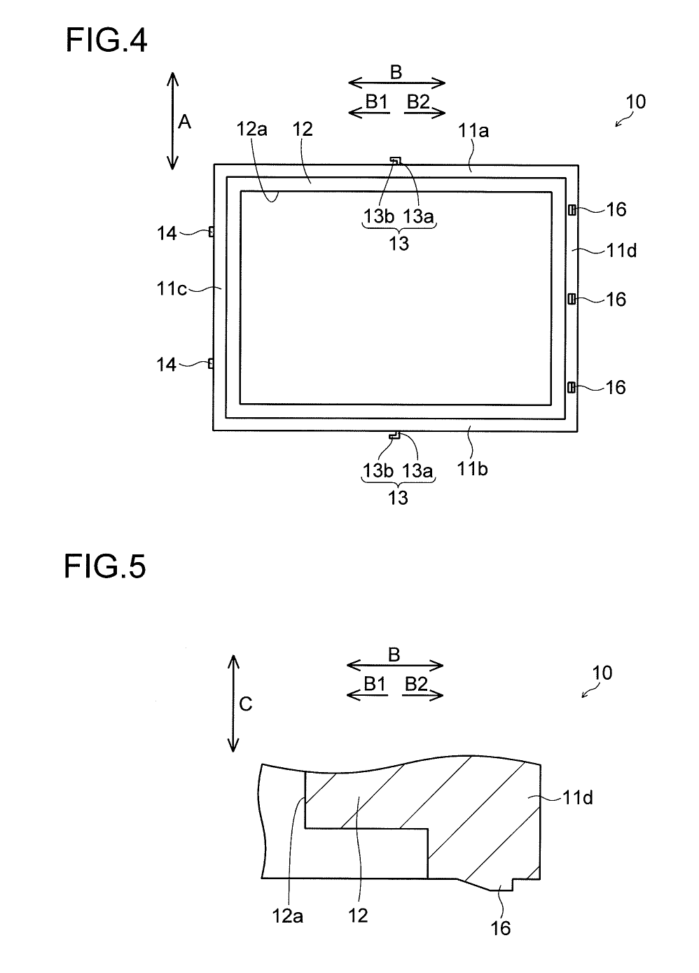

Besides, as shown in FIG. 4, a rear surface (lower surface) of the side wall portion 11d is integrally provided with a plurality of (three) hook portions 16 that protrude backward (downward) and engage with later-described engagement holes 33 (see FIG. 1) of the rear side bezel 30. In other words, the hook portion 16 is formed near the end portion in the B2 direction of the frame 10. Besides, the hook portion 16, as shown in FIG. 5, is formed to have a trapezoidal sectional shape, and an end surface of the hook portion 16 in the B2 direction is formed to be perpendicular to a rear surface (lower surface) of the side wall portion 11d.

Besides, as shown in FIG. 1 and FIG. 2, on a front surface (upper surface) of the base portion 12 (see FIG. 2), a peripheral portion of the liquid crystal display panel 2 (see FIG. 1) is placed. Besides, as shown in FIG. 2, the base portion 12 is provided with an opening portion 12a.

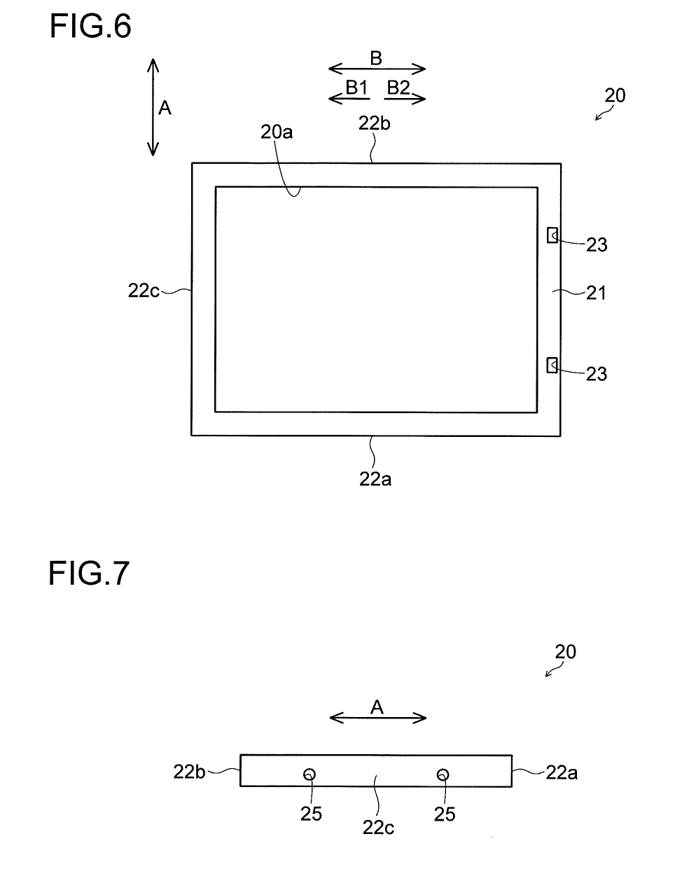

The front side bezel 20, as shown in FIG. 1 and FIG. 6, is formed of a metal plate, and when viewed from top, is made to be a rectangular frame shape. Besides, the front side bezel 20, when viewed from top, is formed to be slightly larger than the frame 10 and the rear side bezel 30.

Besides, the front side bezel 20 includes: a front surface portion 21; a pair of side wall portions 22a and 22b that are disposed to oppose each other; and a side wall portion 22c (see FIG. 6 and FIG. 7) that is disposed in the B1 direction. Here, an end portion of the front side bezel 20 in the B2 direction is not provided with a side wall portion.

Besides, the front side bezel 20 (front surface portion 21), as shown in FIG. 1, is provided with an opening portion 20a that corresponds to a display region of the liquid crystal display panel 2.

Besides, the front surface portion 21 is provided with a plurality of (two) engagement holes 23 at positions that correspond to the hook portions 15 of the frame 10. In other words, the engagement hole 23 is formed near the end portion of the front side bezel 20 in the B2 direction.

Besides, the engagement hole 23 is formed to be engaged with the hook portion 15 when the protrusion portion 13 of the frame 10 is slid in the B1 direction along a portion 24b of a later-described cutout portion 24 of the front side bezel 20. Besides, the engagement hole 23 has a function to alleviate the hook portion 15 (frame 10) moving in the B2 direction.

The pair of side wall portions 22a and 22b are provided with the cutout portions 24 to correspond to the protrusion portions 13 of the frame 10. The cutout portion 24 is formed to be an L shape, and includes: a portion 24a that extends in a direction (C direction) which meets (intersects) a surface direction of the liquid crystal display panel 2 at right angles; and the portion 24b that is connected to the portion 24a and extends in the B1 direction along the surface direction of the liquid crystal display panel 2. Here, the cutout portion 24 is an example of a “guide portion” of the present invention. Besides, the portion 24a is an example of a “second guide portion”, and the portion 24b is an example of a “first guide portion” of the present invention.

The side wall portion 22c (end portion of the front side bezel 20 in the B1 direction), as shown in FIG. 7, is provided with the circular positioning hole 25 at positions that correspond to the positioning portions 14 (see FIG. 2) of the frame 10.

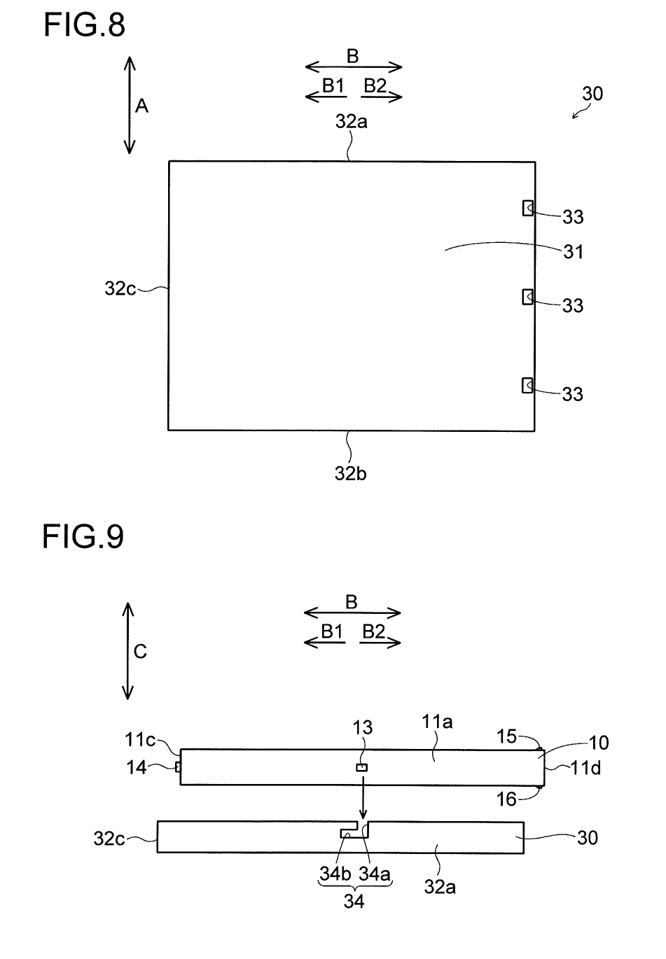

The rear side bezel 30, as shown in FIG. 1 and FIG. 8, is formed of a metal plate, and when viewed from top, is formed to be a rectangular shape. Besides, the rear side bezel 30, when viewed from top, is made to be slightly larger than the frame 10.

Besides, the rear side bezel 30, as shown in FIG. 1, includes: a rear surface portion 31; a pair of side wall portions 32a and 32b; and a side wall portion 32c that is disposed in the B1 direction. Here, an end portion of the rear side bezel 30 in the B2 direction is not provided with a side wall portion.

The rear surface portion 31 is provided with a plurality of (three) engagement holes 33 at positions that correspond to the hook portions 16 (see FIG. 4) of the frame 10. In other words, the engagement hole 33 is formed near the end portion of the rear side bezel 30 in the B2 direction.

Besides, the engagement hole 33 is formed to be engaged with the hook portion 16 (see FIG. 4) when the protrusion portion 13 of the frame 10 is slid in the B1 direction along a portion 34b of a later-described cutout portion 34 of the rear side bezel 30. Besides, the engagement hole 33 has a function to alleviate the hook portion 16 (frame 10) moving in the B2 direction.

The pair of side wall portions 32a and 32b are provided with the cutout portions 34 to correspond to the protrusion portions 13 of the frame 10. The cutout portion 34 is formed to be an L shape, and includes: a portion 34a that extends in the direction (C direction) which meets the surface direction of the liquid crystal display panel 2 at right angles; and a portion 34b that is connected to the portion 34a and extends in the B1 direction along the surface direction of the liquid crystal display panel 2. Here, the cutout portion 34 is an example of the “guide portion” of the present invention. Besides, the portion 34a is an example of the “second guide portion” of the present invention, and the portion 34b is an example of the “first guide portion” of the present invention.

The side wall portion 32c (end portion of the rear side bezel 30 in the B1 direction) is provided with the circular positioning holes 35 at positions that correspond to the positioning portions 14 of the frame 10.

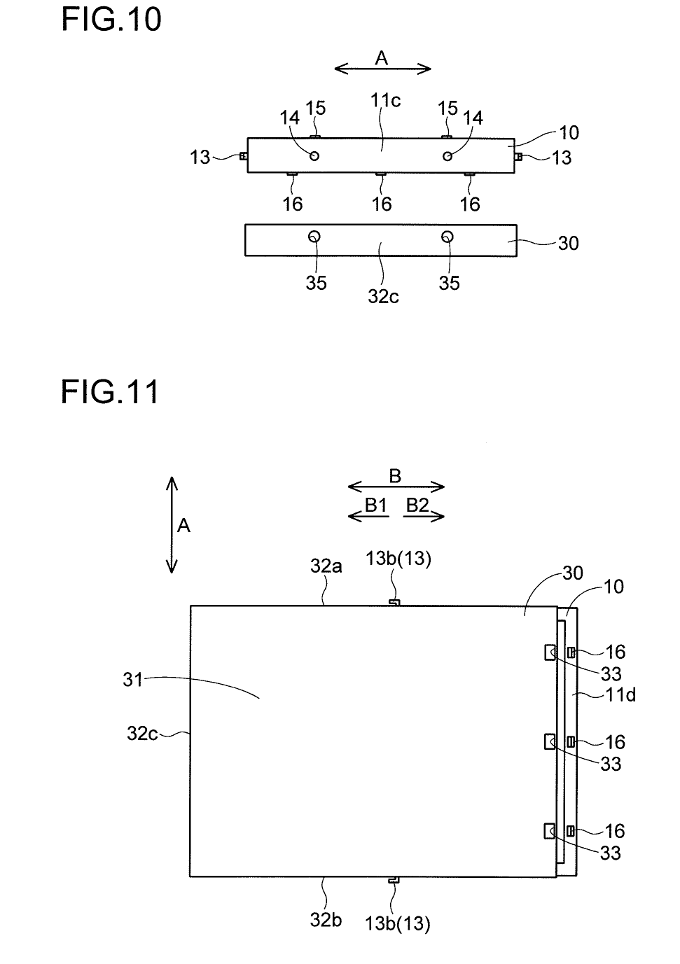

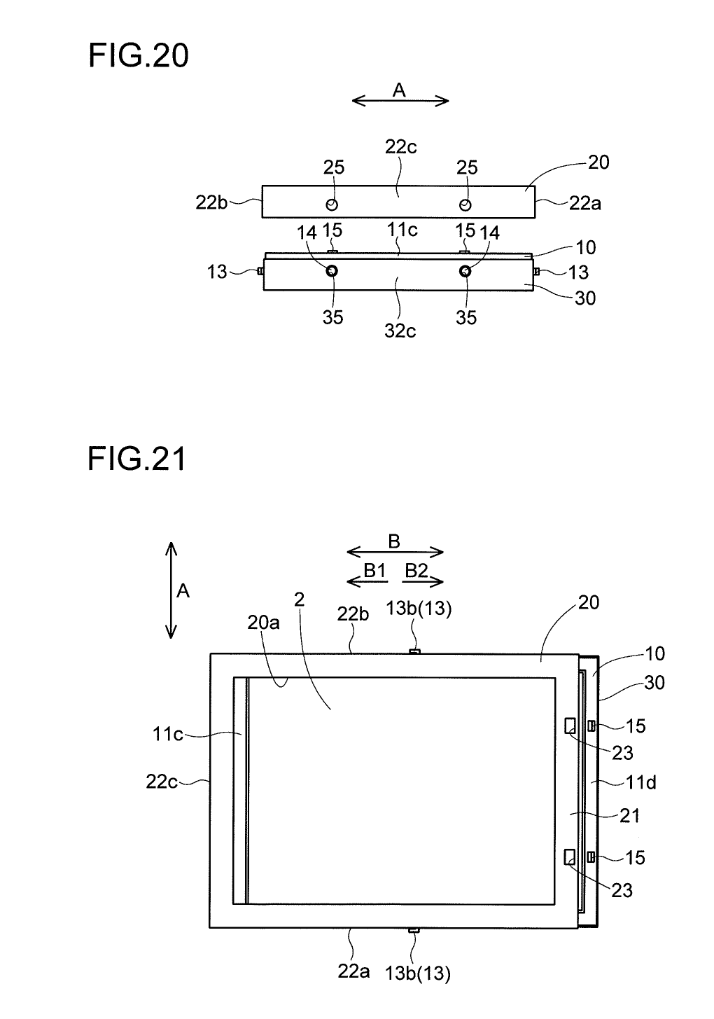

Next, with reference to FIG. 9 to FIG. 28, an assembly method and a disassembly method of the liquid crystal display device 1 according to the embodiment of the present invention are described.

In a case of assembling the liquid crystal display device 1, as shown in FIG. 9 to FIG. 11, the rear side bezel 30 is disposed at a predetermined position of the rear side (lower side) of the frame 10.

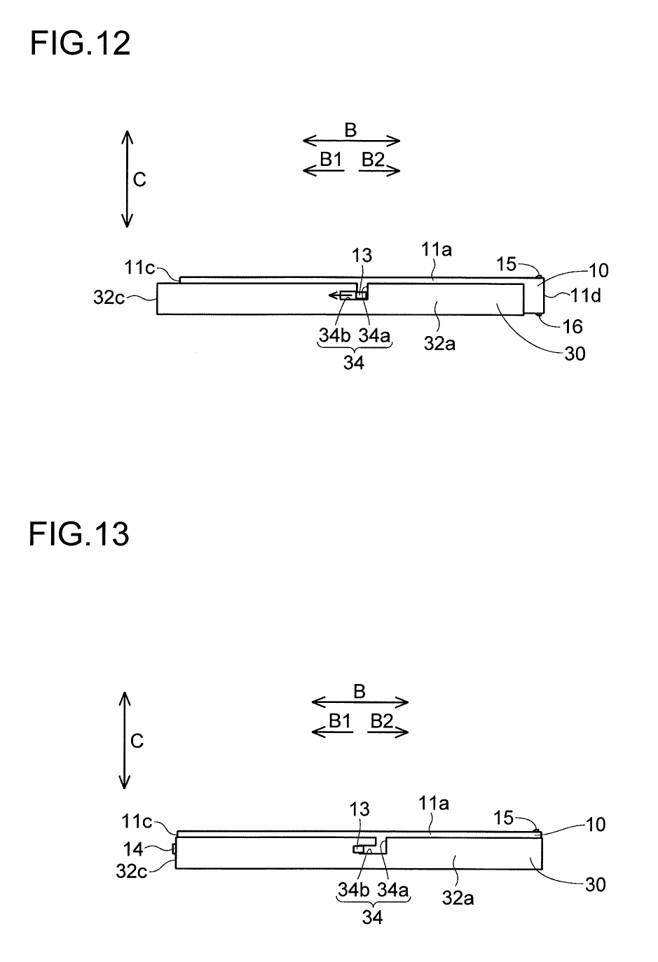

And, the rear side bezel 30 is moved in a forward direction (upward direction) (or the frame 10 is moved in a backward direction (downward direction)), whereby as shown in FIG. 12, the rear side bezel 30 is fitted to the frame 10 from the rear side (lower side). At this time, the protrusion portion 13 of the frame 10 is guided by the portion 34a of the cutout portion 34 of the rear side bezel 30 and moved in the backward direction (downward direction) with respect to the rear side bezel 30.

Thereafter, the rear side bezel 30 is slid in the B2 direction (or the frame 10 is slid in the B1 direction), whereby as shown in FIG. 13 to FIG. 15, the rear side bezel 30 is fixed to the frame 10.

At this time, the protrusion portion 13 of the frame 10 is guided by the portion 34b (see FIG. 13) of the cutout portion 34 of the rear side bezel 30 and slid in the B1 direction with respect to the rear side bezel 30. According to this, as shown in FIG. 13, the protrusion portion 13 of the frame 10 is engaged with the cutout portion 34, and it becomes possible to alleviate the rear side bezel 30 moving in (coming off) the backward direction (downward direction) with respect to the frame 10.

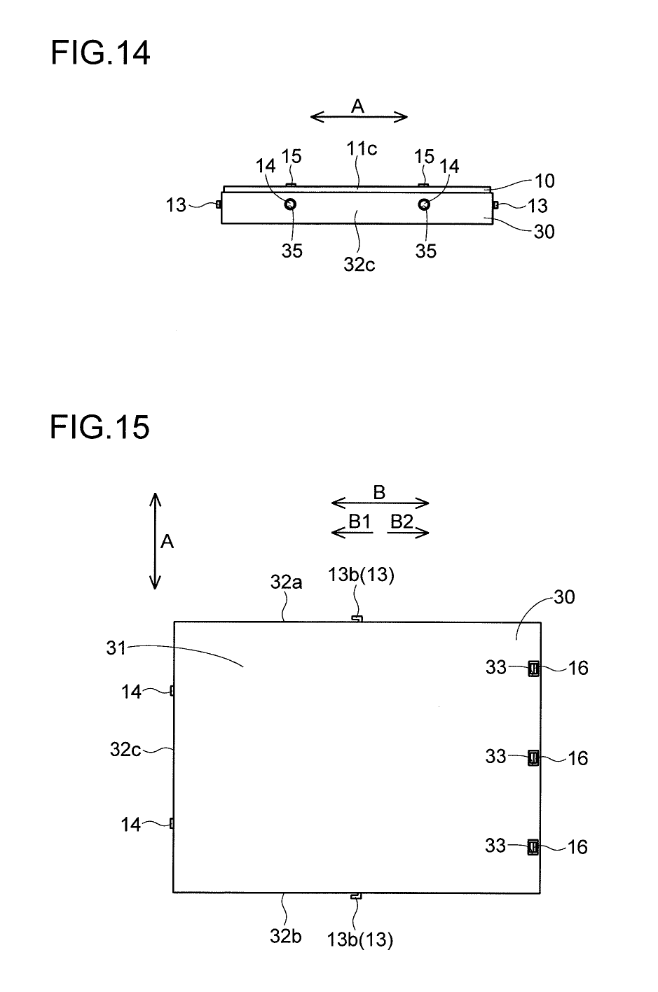

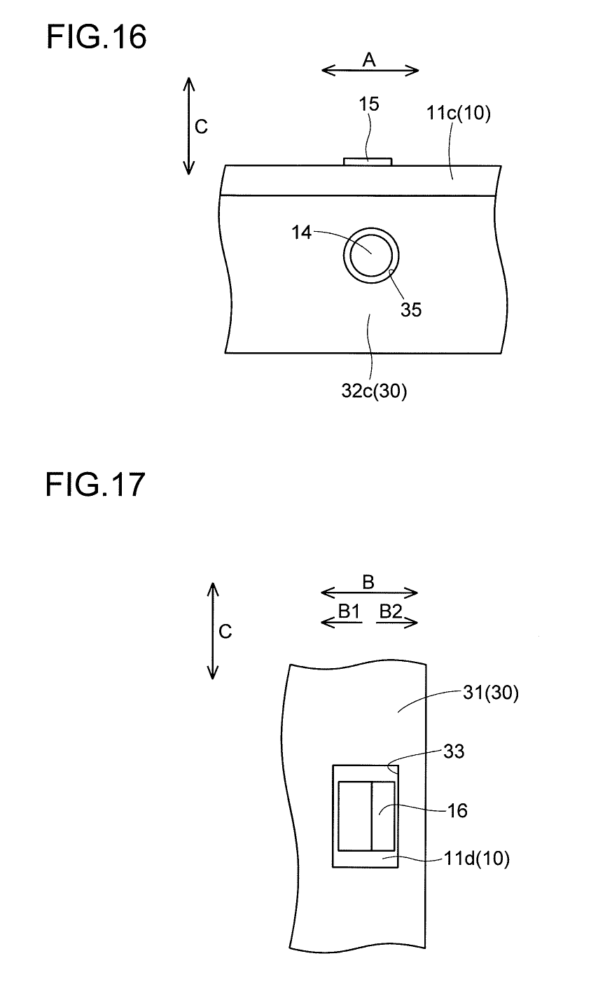

Besides, at this time, as shown in FIG. 14 and FIG. 16, the positioning portion 14 of the frame 10 is inserted into (engaged with) the positioning hole 35 of the rear side bezel 30. According to this, in the B1 direction, the rear side bezel 30 is positioned with respect to the frame 10, and it becomes possible to alleviate the rear side bezel 30 moving in (coming off) the backward direction (downward direction) with respect to the frame 10.

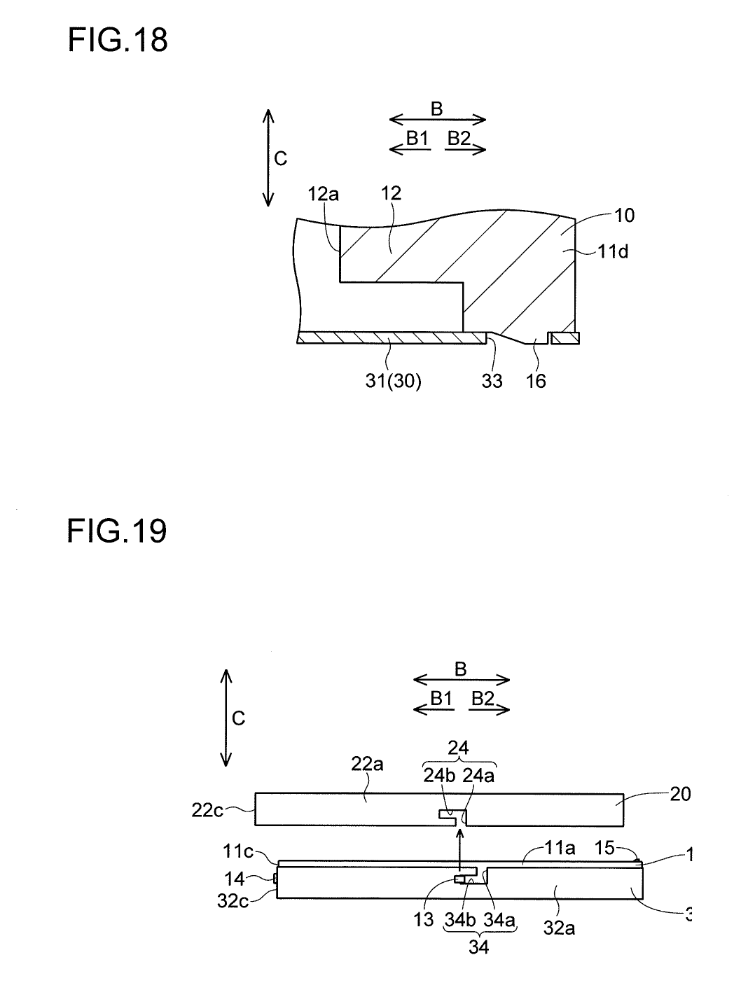

Besides, at this time, as shown in FIG. 15, FIG. 17 and FIG. 18, the hook portion 16 of the frame 10 is engaged with the engagement hole 33 of the rear side bezel 30. According to this, it becomes possible to alleviate the rear side bezel 30 moving in (coming off) the B1 direction with respect to the frame 10.

Next, as shown in FIG. 19 to FIG. 21, the front side bezel 20 is disposed at a predetermined position of the front side (upper side) of the frame 10.

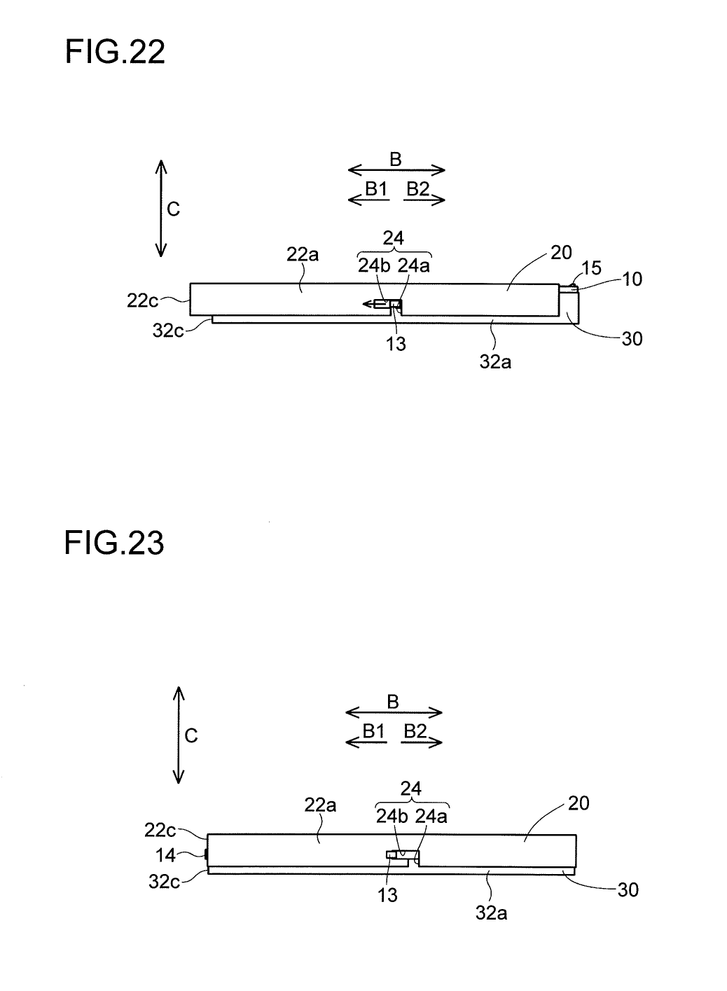

And, the front side bezel 20 is moved in the backward direction (downward direction) (or the frame 10 and the rear side bezel 30 are moved in the frontward direction (upward direction)), whereby as shown in FIG. 22, the front side bezel 20 is fitted to the frame 10 from the front side (upper side). At this time, the protrusion portion 13 of the frame 10 is guided by the portion 24a of the cutout portion 24 of the front side bezel 20 and moved in the forward direction (upward direction) with respect to the front side bezel 20.

Thereafter, the front side bezel 20 is slid in the B2 direction (or the frame 10 and the rear side bezel 30 are slid in the B1 direction), whereby as shown in FIG. 23 to FIG. 25, the front side bezel 20 is fixed to the frame 10.

At this time, the protrusion portion 13 of the frame 10 is guided by the portion 24b (see FIG. 23) of the cutout portion 24 of the front side bezel 20 and slid in the B1 direction with respect to the front side bezel 20. According to this, as shown in FIG. 23, the protrusion portion 13 of the frame 10 is engaged with the cutout portion 24, and it becomes possible to alleviate the front side bezel 20 moving in (coming off) the forward direction (upward direction) with respect to the frame 10.

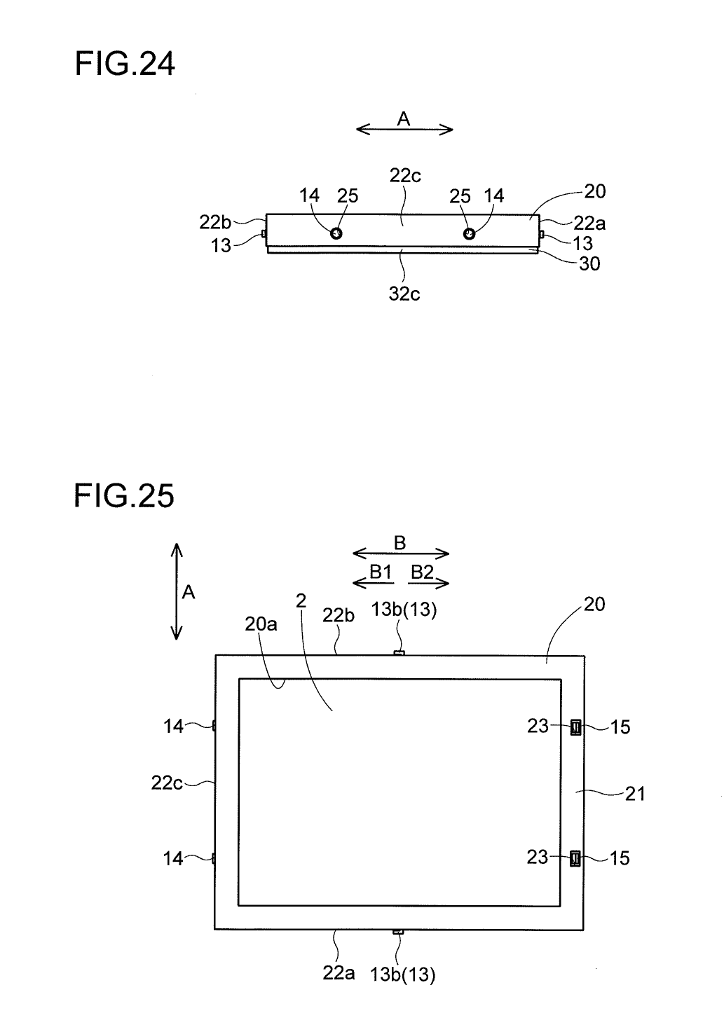

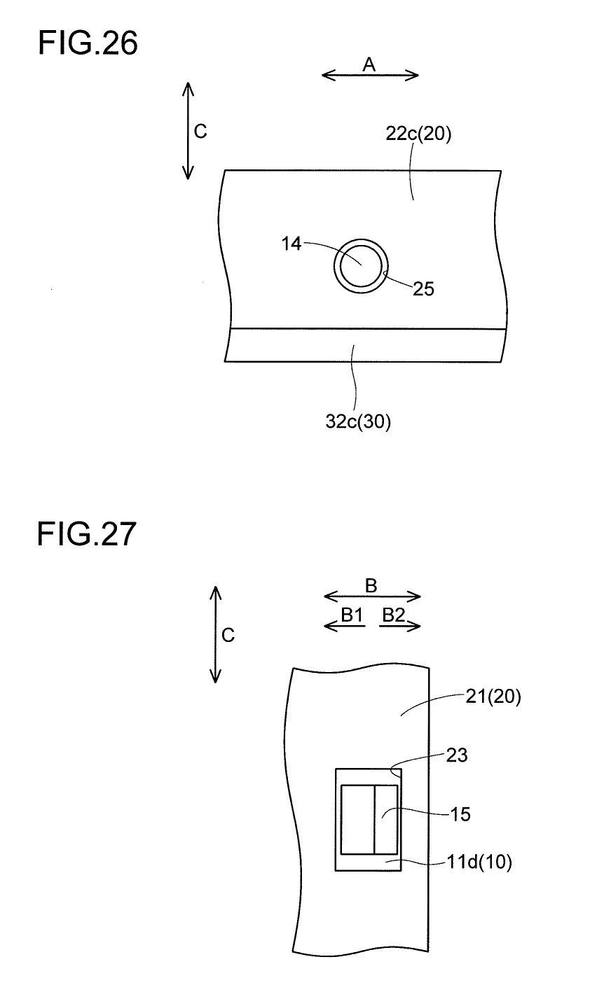

Besides, at this time, as shown in FIG. 24 and FIG. 26, the positioning portion 14 of the frame 10 is inserted into (engaged with) the positioning hole 25 of the front side bezel 20. According to this, in the B1 direction, the front side bezel 20 is positioned with respect to the frame 10, and it becomes possible to alleviate the front side bezel 20 moving in (coming off) the forward direction (upward direction) with respect to the frame 10.

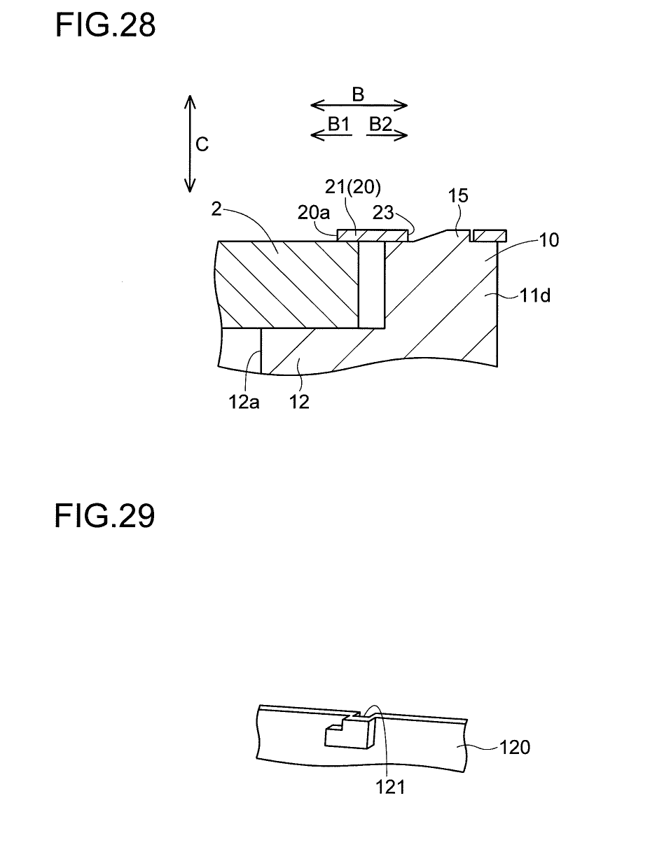

Besides, at this time, as shown in FIG. 25, FIG. 27 and FIG. 28, the hook portion 15 of the frame 10 is engaged with the engagement hole 23 of the front side bezel 20. According to this, it becomes possible to alleviate the front side bezel 20 moving in (coming off) the B1 direction with respect to the frame 10.

In this way, the liquid crystal display device 1 is assembled.

On the other hand, in a case of disassembling the liquid crystal display device 1, a peripheral portion (one edge portion in the B2 direction of the four edge portions that compose the front surface portion 21 of the front side bezel 20) of the engagement hole 23 of the front side bezel 20 is widened in the forward direction (upward direction) and the front side bezel 20 is slid in the B1 direction with respect to the frame 10. And, the front side bezel 20 is moved in the forward direction (upward direction) with respect to the frame 10, whereby the front side bezel 20 is demounted from the frame 10.

Thereafter, a peripheral portion of the engagement hole 33 (see FIG. 15) of the rear side bezel 30 is widened in the backward direction (downward direction) and the rear side bezel 30 is slid in the B1 direction with respect to the frame 10. And, the rear side bezel 30 is moved in the backward direction (downward direction) with respect to the frame 10, whereby the rear side bezel 30 is demounted from the frame 10.

In this way, the liquid crystal display device 1 is disassembled.

In the present embodiment, as described above, the frame 10 is provided with the protrusion portion 13 and the hook portion 16; and the rear side bezel 30 is provided with the cutout portion 34 engaged with the protrusion portion 13 and the engagement hole 33 that is engaged with the hook portion 16 when the protrusion portion 13 is slid in the B1 direction along the portion 34b of the cutout portion 34. According to this, by sliding the protrusion portion 13 in the B1 direction along the cutout portion 34, it is possible to engage the hook portion 16 with the engagement hole 33 and fix the rear side bezel 30 to the frame 10. Likewise, the frame 10 is provided with the protrusion portion 13 and the hook portion 15; and the front side bezel 20 is provided with the cutout portion 24 engaged with the protrusion portion 13 and the engagement hole 23 that is engaged with the hook portion 15 when the protrusion portion 13 is slid in the B1 direction along the portion 24b of the cutout portion 24. According to this, by sliding the protrusion portion 13 in the B1 direction along the cutout portion 24, it is possible to engage the hook portion 15 with the engagement hole 23 and fix the front side bezel 20 to the frame 10. In other words, it is possible to assemble the liquid crystal display device 1 without using a screw, accordingly, it is possible to improve the assembly workability and shorten the assembly time of the liquid crystal display device 1. Besides, it is also possible to improve the workability when disassembling the liquid crystal display device 1, accordingly, it is also possible to shorten the disassembly time of the liquid crystal display device 1.

Besides, in the present embodiment, as described above, by forming the portion 34b of the cutout portion 34 to extend in the B1 direction, by means of the protrusion portion 13 and the portion 34b of the cutout portion 34, it is possible to alleviate the rear side bezel 30 moving (coming off) backward (downward) with respect to the frame 10. Likewise, by forming the portion 24b of the cutout portion 24 to extend in the B1 direction, by means of the protrusion portion 13 and the portion 24b of the cutout portion 24, it is possible to alleviate the front side bezel 20 moving (coming off) frontward (upward) with respect to the frame 10.

Besides, by forming the engagement hole 33 of the rear side bezel 30 to alleviate the hook portion 16 moving in the B1 direction, it is possible to alleviate the rear side bezel 30 moving in the B1 direction with respect to the frame 10. In other words, it is possible to alleviate the rear side bezel 30 coming off the frame 10. Besides, by forming the engagement hole 23 of the front side bezel 20 to alleviate the hook portion 15 moving in the B1 direction, it is possible to alleviate the front side bezel 20 moving in the B1 direction with respect to the frame 10. In other words, it is possible to alleviate the front side bezel 20 coming off the frame 10.

Besides, in the present embodiment, as described above, by disposing the hook portions 15 and 16 on the one outer wall portion 11d of the plurality of outer wall portions 11a to 11d, compared with a case where the hook portions 15 and 16 are disposed, for example, on two or more outer wall portions of the plurality of outer wall portions 11a to 11d, it is possible to decrease the fixing (engagement) portions, accordingly, it is possible to more improve the workability when demounting the front side bezel 20 and the rear side bezel 30 from the frame 10. According to this, it is possible to more shorten the disassembly time of the liquid crystal display device 1. Here, for example, in a case where the hook portions 15 and 16 are disposed on the four edges (four outer wall portions 11a to 11d) of the frame 10, thanks to dimensional unevenness of the components, a difference occurs in the fitting workability (or demounting workability). Specifically, a disadvantage occurs, in which it is easy to fit in (or demount from) two edges (two outer wall portions 11a and 11b) but hard to fit (or hard to demount) in the remaining two edges (two outer wall portions 11c and 11d) and the like.

Besides, in the present embodiment, as described above, by disposing the hook portion 16 near the end portion of the frame 10 in the slide direction (B2 direction) of the rear side bezel 30 during the assembly time, during the time the rear side bezel 30 is slid with respect to the frame 10, it is possible to alleviate the hook portion 16 touching the rear side bezel 30. According to this, it is possible to alleviate the rear side bezel 30 becoming hard to slide with respect to the frame 10, accordingly, it is possible to more alleviate the assembly workability and disassembly workability of the liquid crystal display device 1 deteriorating. Likewise, by disposing the hook portion 15 near the end portion of the frame 10 in the slide direction (B2 direction) of the front side bezel 20 during the assembly time, during the time the front side bezel 20 is slid with respect to the frame 10, it is possible to alleviate the hook portion 15 touching the front side bezel 20. According to this, it is possible to alleviate the front side bezel 20 becoming hard to slide with respect to the frame 10, accordingly, it is possible to more alleviate the assembly workability and disassembly workability of the liquid crystal display device 1 deteriorating.

Besides, in the present embodiment, as described above, the cutout portion 34 of the rear side bezel 30 is provided with the portion 34a that extends in the direction (C direction) that meets the surface direction of the liquid crystal display panel 2 at right angles. According to this, by moving the protrusion portion 13 along the portion 34a, thereafter, sliding along the portion 34b, it is possible to easily fix the rear side bezel 30 to the frame 10. Likewise, the cutout portion 24 of the front side bezel 20 is provided with the portion 24a that extends in the direction (C direction) that meets the surface direction of the liquid crystal display panel 2 at right angles. According to this, by moving the protrusion portion 13 along the portion 24a, thereafter, sliding along the portion 24b, it is possible to easily fix the front side bezel 20 to the frame 10.

Besides, by disposing the portion 34a on the cutout portion 34, compared with a case where the cutout portion 34 is disposed on a portion only that extends in the B1 direction (case where the portion 34b is formed till the end portion in the B2 direction), it is possible to shorten the moving (slide) distance of the rear side bezel 30 with respect to the frame 10. According to this, it is possible to improve the assembly workability and disassembly workability of the liquid crystal display device 1. Likewise, by disposing the portion 24a on the cutout portion 24, compared with a case where the cutout portion 24 is disposed on a portion only that extends in the B1 direction (case where the portion 24b is formed till the end portion in the B2 direction), it is possible to shorten the moving (slide) distance of the front side bezel 20 with respect to the frame 10. According to this, it is possible to improve the assembly workability and disassembly workability of the liquid crystal display device 1.

Besides, in the present embodiment, as described above, the frame 10 is provided with the positioning portions 14, and the front side bezel 20 and the rear side bezel 30 are provided with the positioning holes 25 and 35 that engage with the positioning portions 14. According to this, in the B1 direction, it is possible to fix the front side bezel 20 and the rear side bezel 30 to the frame 10 with high accuracy, and it is possible to alleviate the front side bezel 20 and the rear side bezel 30 moving in (coming off) the C direction with respect to the frame 10.

Besides, in the present embodiment, as described above, the protrusion portion 13 of the frame 10 is engaged with both of the cutout portion 24 of the front side bezel 20 and the cutout portion 34 of the rear side bezel 30. According to this, it is not necessary to dispose separately the protrusion portion 13 for fixing the front side bezel 20 and the protrusion portion 13 for fixing the rear side bezel 30. Here, in a case where the protrusion portion 13 for the front side bezel 20 and the protrusion portion 13 for the rear side bezel 30 are separately disposed, it is necessary to dispose a cutout portion on the rear side bezel 30 for avoiding the protrusion portion 13 for the front side bezel 20.

Besides, in the present embodiment, as described above, the positioning portion 14 of the frame 10 is engaged with both of the positioning hole 25 of the front side bezel 20 and the positioning hole 35 of the rear side bezel 30. According to this, it is not necessary to dispose separately the positioning portion 14 for fixing the front side bezel 20 and the positioning portion 14 for fixing the rear side bezel 30. Here, in a case where the positioning portion 14 for the front side bezel 20 and the positioning portion 14 for the rear side bezel 30 are separately disposed, it is necessary to dispose a cutout portion on the rear side bezel 30 for avoiding the positioning portion 14 for the front side bezel 20.

Besides, in the present embodiment, as described above, by disposing the protrusion portion 13 on the pair of outer wall portions 11a and 11b of the plurality of outer wall portions 11a to 11d that are disposed to oppose each other, it is possible to more alleviate the front side bezel 20 and the rear side bezel 30 coming off the frame 10.

Besides, in the present embodiment, as described above, by forming the cutout portions 24 and 34, which engage with the protrusion portions 13 of the frame 10, on the front side bezel 20 and the rear side bezel 30, compared with a case where for example, a concave-shaped guide portion (dimple), which engages with the protrusion portion 13 of the frame 10, is formed on the front side bezel 20 and the rear side bezel 30, it is possible to easily form the portions (cutout portions 24 and 34) which engage with the protrusion portion 13 of the frame 10.

Besides, in the present embodiment, as described above, by forming the protrusion portion 13 to protrude in the A direction outward from the front side bezel 20 and the rear side bezel 30, it is possible to more alleviate the protrusion portion 13 coming off the cutout portions 24 and 34. According to this, it is possible to more alleviate the front side bezel 20 and the rear side bezel 30 coming off the frame 10.

Besides, in the present embodiment, as described above, by forming the protrusion portion 13 to be the L shape, it is possible to more alleviate the protrusion portion 13 coming off the cutout portions 24 and 34, accordingly, it is possible to more alleviate the front side bezel 20 and the rear side bezel 30 coming off the frame 10.

Here, it should be considered that the embodiments disclosed this time are examples in all respects and are not limiting. The scope of the present invention is not indicated by the above description of the embodiments but by the claims, and all modifications within the scope of the claims and the meaning equivalent to the claims are covered.

For example, in the above embodiments, the example is described, in which the display device is applied to the liquid crystal display device; however, the present invention is not limited to this, and may be applied to display devices other than the liquid crystal display device.

Besides, in the above embodiments, the example is described, in which there disposed are the front side bezel arranged on the front side of the frame and the rear side bezel arranged on the rear side of the frame; however, the present invention is not limited to this, and only one of the front side bezel and the rear side bezel may be disposed.

Besides, in the above embodiments, the example is described, in which the cutout portion (guide portion) is formed on both of the front side bezel and the rear side bezel; however, the present invention is not limited to this, and the cutout portion (guide portion) may be formed only one of the front side bezel and the rear side bezel.

Besides, in the above embodiments, the example is described, in which the protrusion portion is formed on the frame and the guide portion is formed on the bezel (the front side bezel and the rear side bezel); however, the present invention is not limited to this, and the protrusion portion may be formed on the bezel (front side bezel and rear side bezel) and the guide portion may be formed on the frame. Here, in the case where the guide portion is formed on the resin frame, a slide core becomes necessary for a forming mold of the frame, a structure of the forming mold becomes complicated, and the cost becomes high, accordingly, it is preferable to form the protrusion portion on the frame and form the guide portion on the bezel (front side bezel and rear side bezel).

Besides, in the above embodiments, the example is described, in which the hook portion is formed on the frame and the engagement hole is formed in the bezel (front side bezel and rear side bezel); however, the present invention is not limited to this, and the hook portion, which protrudes backward (downward), may be formed on the bezel (front side bezel and rear side bezel), and the engagement hole may be formed in the frame. In this case, the hook portion may be formed near an end portion of the bezel in a direction (B1 direction) opposite to the slide direction of the bezel with respect to the frame.

Besides, in the above embodiments, the example is described, in which the protrusion portion and the hook portion are formed on the frame and the cutout portion and the engagement hole are formed on and in the bezel (front side bezel and rear side bezel); however, the present invention is not limited to this, and the protrusion portion and the hook portion may be formed on separate members (frame and bezel) and the cutout portion and the engagement hole may also be formed on separate members (frame and bezel). This also applies to the positioning portion and the positioning hole, and for example, the positioning portion and the protrusion portion may be formed on the same member, or the positioning portion and the protrusion portion may be formed on separate members.

Besides, in the above embodiments, the example is described, in which the positioning portion is formed on the frame and the positioning hole is formed in the bezel (front side bezel and rear side bezel); however, the present invention is not limited to this, and the positioning portion may be formed on the bezel (front side bezel and rear side bezel) and the positioning hole may be formed in the frame. Besides, the positioning portion and the positioning hole may not be formed.

Besides, in the above embodiments, the example is described, in which the positioning portion of the frame is formed to be the cylindrical shape or the conical trapezoidal shape; however, the present invention is not limited to this, and the positioning portion of the frame may be formed to be a polygonal shape or a polyhedral pyramidal trapezoidal shape.

Besides, in the above embodiments, the example is described, in which the frame is formed of the resin and the bezel (front side bezel and rear side bezel) is formed of the metal plate; however, the present invention is not limited to this, and the frame may be formed of a material other than the resin, and the bezel (front side bezel and rear side bezel) may be formed of a material other than the metal plate.

Besides, in the above embodiments, the example is described, in which the protrusion portion, which engages with both of the guide portion (cutout portion) of the front side bezel and the guide portion (cutout portion) of the rear side bezel, is formed on the frame; however, the present invention is not limited to this, and the protrusion portion for engaging with the guide portion (cutout portion) of the front side bezel and the protrusion portion for engaging with the guide portion (cutout portion) of the rear side bezel may be formed on separate members.

Besides, in the above embodiments, the example is described, in which the positioning portion, which engages with both of the positioning hole of the front side bezel and the positioning hole of the rear side bezel, is formed on the frame; however, the present invention is not limited to this, and the positioning portion for engaging with the positioning hole of the front side bezel and the positioning portion for engaging with the positioning hole of the rear side bezel may be separately formed on the frame.

Besides, in the above embodiments, the example is described, in which the protrusion portion of the frame is formed to be the L shape; however, the present invention is not limited to this, and the protrusion portion of the frame may be formed to be a cylindrical shape or a polygonal shape.

Besides, in the above embodiments, the example is described, in which the cutout portion for engaging with the protrusion portion of the frame is formed on the front side bezel and the rear side bezel; however, the present invention is not limited to this, and as in a first modification of the present invention shown in FIG. 29, a concave-shaped guide portion 121 for engaging with the protrusion portion of the frame may be formed on a bezel 120 (front side bezel and rear side bezel). Here, it is easier to form the cutout portion on the metal-plate bezel 120 than to form a dimple (concave-shaped guide portion 121) in production and the cost becomes inexpensive, accordingly, it is preferable to form the cutout portion on the metal-plate bezel.

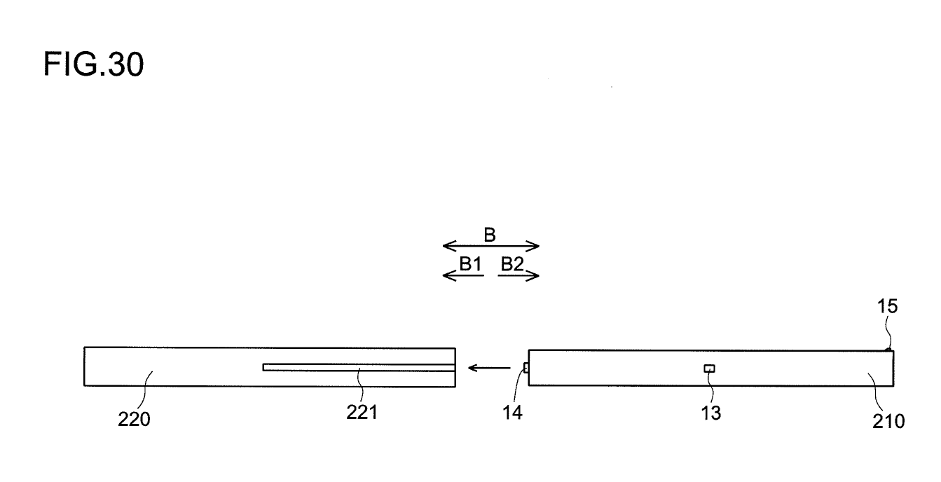

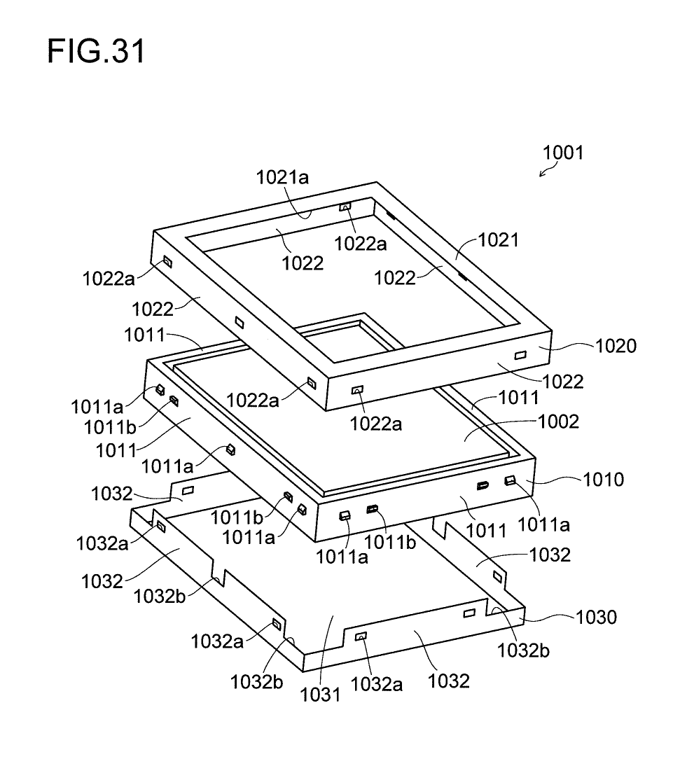

Besides, in the above embodiments, the example is described, in which the front side bezel and the rear side bezel are formed of the separate members; however, the present invention is not limited to this, and as in a second modification of the present invention shown in FIG. 30, a bezel 220, in which the front side bezel and the rear side bezel are integrally formed with each other, may be used. In this case, a guide portion (a concave portion (dimple) or a cutout portion) 221 extending in only the B direction is formed on the bezel 220, and a frame 210 is inserted from a side of the bezel 220. Besides, in this case, the hook portion 15 may be formed, for example, on only a front surface (upper surface) of the frame 210. Here, in the case where the front side bezel and the rear side bezel are integrally formed with each other, it is necessary to weld the front side bezel and the rear side bezel to each other, whereby the productivity (workability) deteriorates and the slide distance of the frame 210 with respect to the bezel 220 becomes large. Because of this, it is preferable to separately form the front side bezel and the rear side bezel.

Besides, in the above embodiments, the example is described, in which after the rear side bezel is fixed to the frame, the front side bezel is fixed to the frame; however, the present invention is not limited to this, and after the front side bezel is fixed to the frame, the rear side bezel may be fixed to the frame. In this case, the rear side bezel may be formed slightly larger than the front side bezel.

Besides, in the above embodiments, the example is described, in which the hook portion is formed on the front surface (upper surface) and rear surface (lower surface) of the frame; however, the present invention is not limited to this, and the hook portion may be formed on a side surface (a side surface of the side wall portion 11a or a side surface of the side wall portion 11b) of the frame. In this case, the hook portion for the front side bezel may be formed on one of the side wall portions 11a and 11b. Besides, likewise, the hook portion for the rear side bezel may be formed on one or the other of the side wall portions 11a and 11b.

### REFERENCE SIGNS LIST

1 liquid crystal display device (display device)
2 liquid crystal display panel (display panel)
10, 210 frames
11a, 11b side wall portions (outer edge portions, a pair of outer edge portions)
11c, 11d side wall portions (outer edge portions)
13 protrusion portion
14 positioning portion
15, 16 hook portions
20 front side bezel (bezel)
23, 33 engagement holes
24, 34 cutout portions (guide portions)
24a, 34a portions (second guide portions)
24b, 34b portions (first guide portions)
25, 35 positioning holes
30 rear side bezel (bezel)
120, 220 bezels
121, 221 guide portions

1. A display device comprising:
a frame that holds a display panel; and
a bezel that is disposed on at least one of a front side and a rear side of the frame; wherein
one of the frame and the bezel is provided with a protrusion portion;
the other of the frame and the bezel is provided with a guide portion that includes a first guide portion which is engaged with the protrusion portion and extends in a first direction along a surface direction of the display panel;
one of the frame and the bezel is provided with a hook portion;
the other of the frame and the bezel is provided with an engagement hole that is engaged with the hook portion when the protrusion portion is slid in the first direction along the first guide portion of the guide portion; and
the engagement hole has a function to alleviate the hook portion moving in a direction along the first direction.

2. The display device according to claim 1, wherein
the frame includes a plurality of outer edge portions; and
the hook portion or the engagement hole is disposed on or in one outer edge portion of the plurality of outer edge portions.

3. The display device according to claim 1, wherein
in a case where the hook portion is disposed on the frame, the hook portion is disposed near an end portion of the frame in a slide direction of the bezel when mounting the bezel on the frame; and
in a case where the hook portion is disposed on the bezel, the hook portion is disposed near an end portion of the bezel in a direction opposite to the slide direction.

4. The display device according to claim 1, wherein
the guide portion includes a second guide portion that is connected to the first guide portion and extends in a direction which intersects the surface direction of the display panel.

5. The display device according to claim 1, wherein
an end portion of one of the frame and the bezel in a direction opposite to the slide direction of the bezel when mounting the bezel on the frame is provided with a positioning portion that protrudes in a direction along the slide direction; and
an end portion of the other of the frame and the bezel in the direction opposite to the slide direction is provided with a positioning hole that engages with the positioning portion.

6. The display device according to claim 5, wherein
the frame is formed of a resin; and
the positioning portion is formed integrally with the frame.

7. The display device according to claim 1, wherein
the frame is formed of a resin; and
the protrusion portion is formed integrally with the frame.

8. The display device according to claim 1, wherein
the frame is formed of a resin; and
the hook portion is formed integrally with the frame.

9. The display device according to claim 1, wherein
the bezel includes a front side bezel disposed on the front side of the frame and a rear side bezel disposed on the rear side of the frame.

10. The display device according to claim 9, wherein
the protrusion portion is disposed on the frame;
the guide portion is disposed on the front side bezel and the rear side bezel; and
the protrusion portion of the frame is engaged with both of the guide portion of the front side bezel and the guide portion of the rear side bezel.

11. The display device according to claim 9, wherein
an end portion of the frame in the direction opposite to the slide direction of the bezel when mounting the bezel on the frame is provided with a positioning portion that protrudes in the direction along the slide direction;
an end portion of the front side bezel and an end portion of the rear side bezel in the direction opposite to the slide direction are provided with a positioning hole that engages with the positioning portion; and
the positioning portion of the frame is engaged with both of the positioning hole of the front side bezel and the positioning hole of the rear side bezel.

12. The display device according to claim 1, wherein
the frame includes a plurality of outer edge portions; and
the protrusion portion or the guide portion is disposed on a pair of outer edge portions of the plurality of outer edge portions that are disposed to oppose each other.

13. The display device according to claim 1, wherein
the guide portion includes a cutout portion.

14. The display device according to claim 13, wherein
the protrusion portion is disposed on the frame and protrudes outward from the bezel.

15. The display device according to claim 1, wherein
the protrusion portion is formed to be an L shape.
